(19) United States
(12) Patent Application Publication
(10) Pub. No.: US 2019/0267317 A1
(43) Pub. Date: Aug. 29, 2019

(54) SUBSTRATE HAVING NON-THROUGH HOLE

(71) Applicant: AGC Inc., Chiyoda-ku (JP)

(72) Inventors: Kohei HORIUCHI, Tokyo (JP); Yoichiro SATO, Tokyo (JP)

(73) Assignee: AGC inc., Chiyoda-ku (JP)

(21) Appl. No.: 16/409,178

(22) Filed: May 10, 2019

Related U.S. Application Data
(63) Continuation of application No. PCT/JP2017/040411, filed on Nov. 9, 2017.

(30) Foreign Application Priority Data
Nov. 14, 2016 (JP) 2016-221890

(51) Int. Cl. H01L 23/498; H01L 23/48; H01L 23/528; H01L 21/768; H01L 23/15; H01L 21/48

(52) U.S. Cl. CPC H01L 23/49827; H01L 23/481; H01L 23/5283; H01L 21/486; H01L 23/15; H01L 23/49838; H01L 21/76898

(57) ABSTRACT

A substrate has a non-through hole. The non-through hole has an opening with a diameter ϕ₁ falling within a range of 5 to 200 μm, and a depth d of 30 μm or more. The non-through hole has a rounded end portion, and in a cross section of the non-through hole including a stretching axis of the non-through hole, a shape of the end portion is approximated by a circular arc with a diameter ϕ₂, and a ratio of the diameters ϕ₂/ϕ₁ falls within a range of 0.03 to 0.9. The cross section includes first and second wall lines defining side walls. A tapered angle fouled by a line L and the stretching axis falls within a range of 2° to 80°, the line L passing through a point on the first wall line separated from the opening by a distance 0.1×d and a point by a distance 0.5×d.

### CROSS-REFERENCE TO RELATED APPLICATION

The present application is a continuation application filed under 35 U.S.C. 111(a) claiming benefit under 35 U.S.C. 120 and 365(c) of PCT International Application No. PCT/JP2017/040411 filed on Nov. 9, 2017 and designating the U.S., which claims priority of Japanese Patent Application No. 2016-221890 filed on Nov. 14, 2016. The entire contents of the foregoing applications are incorporated herein by reference.

### BACKGROUND OF THE INVENTION

### 1. Field of the Invention

The disclosure herein generally relates to a substrate having a non-through hole.

### 2. Description of the Related Art

Conventionally, a substrate having through-electrode has been known, in which a fine through-hole disposed in the substrate is filled with a conductive material.

The conventional through-electrode substrate is manufactured by following processes:

(1) Forming a non-through hole in a substrate (non-through hole formation step);

(2) Depositing a metal layer in the non-through hole by using a sputtering method (sputtering step);

(3) Filling the non-through hole with a conductive material by using an electroplating method (electroplating step); and

(4) Removing the conductive material on the surface, on which the non-through hole is formed, by using a chemical mechanical polishing (CMP) method, and grinding the other surface of the substrate, to form a through hole (through hole formation step). See, for example, Aric Shorey, Rachel Lu, Gene Smith, Kevin Adriance, “Advancements in Glass for Packaging Technology”, IMAPS 12th International Conference and Exhibition on Device Packaging, 2016, pp. 000173-000175.

### SUMMARY OF THE INVENTION

### Problem to be Solved by the Invention

In the conventional method of manufacturing a substrate having through-electrode, as described above, there is a problem that a through-hole of the substrate is not sufficiently filled with a conductive material.

The problem in the conventional manufacturing method is caused by a high aspect ratio of a non-through hole, formed in the non-through hole formation step (1). Due to the high aspect ratio, a metal layer is not deposited over an entire surface of the non-through hole (wall surfaces forming the non-through hole) in the sputtering step (2). The metal layer deposited in the sputtering step (2) functions as a seeding layer in the electroplating step (3). Thus, in the electroplating step (3), the conductive material is not plated in a region where the metal layer is not deposited on the wall surface forming the non-through hole. Then, a void appears in the non-through hole, and a through hole, in which the conductive material is not sufficiently filled, is formed.

According to the above described problem, a substrate having a non-through hole has been required, in which a metal layer is properly deposited in the non-through hole.

The present invention has been made in view of the above problem, and aims at providing a substrate having a non-through hole, in which a metal layer is deposited in the non-through hole more easily than the related art.

### Means for Solving Problems

According to an aspect of the present invention, a substrate having a non-through hole,

the non-through hole having an opening with a diameter ϕ₁ that falls within a range of 5 μm to 200 μm, and having a depth d of 30 μm or more,

the non-through hole having a rounded end portion, and in a cross section of the non-through hole including a stretching axis of the non-through hole, a shape of the end portion being approximated by a circular arc with a diameter and a ratio of the diameters ϕ₂/ϕ₁ falling within a range of 0.03 to 0.9,

the cross section including a first wall line and a second wall line that define side walls of the non-through hole, the first wall line and the second wall line being symmetric with respect to the stretching axis of the non-through hole, and

a tapered angle α formed by a line L and the stretching axis falls within a range of 2° to 80°, the line L connecting a point A on the first wall line separated from the opening by a distance d₁ (d₁=0.1×d) in a direction parallel to the stretching axis and a point B on the first wall line separated from the opening by a distance d₂ (d₂=0.5×d) in the direction parallel to the stretching axis, is provided.

### Effects of the Invention

According to the aspect of the present invention, a substrate having a non-through hole, in which a metal layer is deposited more easily in the non-through hole than the related art, is provided.

### BRIEF DESCRIPTION OF THE DRAWINGS

Other objects and further features of embodiments will become apparent from the following detailed description when read in conjunction with the accompanying drawings, in which:

FIG. 1 is a flowchart schematically depicting an example of a method of manufacturing a substrate with through-electrode according to a related art;

FIG. 2 is a diagram schematically depicting a process of the method of manufacturing a substrate with through-electrode according to the related art;

FIG. 3 is a diagram schematically depicting the process of the method of manufacturing a substrate with through-electrode according to the related art;

FIG. 4 is a diagram schematically depicting the process of the method of manufacturing a substrate with through-electrode according to the related art;

FIG. 5 is a diagram schematically depicting the process of the method of manufacturing a substrate with through-electrode according to the related art;

FIG. 6 is an enlarged diagram schematically depicting a cross section of a non-through hole before a sputtering step in the method of manufacturing a substrate with through-electrode according to the related art;

FIG. 7 is an enlarged diagram schematically depicting a cross section of the non-through hole after the sputtering step in the method of manufacturing a substrate with through-electrode according to the related art;

FIG. 8 is a diagram schematically depicting a cross section of a substrate having a non-through holes according to an embodiment of the present invention;

FIG. 9 is an enlarged diagram schematically depicting a cross section of the non-through hole, illustrated in FIG. 8;

FIG. 10 is a diagram for describing a tapered angle α of the non-through hole;

FIG. 11 is a diagram depicting an example of a cross sectional photograph of a non-through hole in a substrate obtained in Example 1;

FIG. 12 is a diagram depicting an example of a cross sectional photograph of a non-through hole in a substrate obtained in Example 2;

FIG. 13 is a diagram depicting an example of a cross sectional photograph of a non-through hole in a substrate obtained in Example 4;

FIG. 14 is a diagram depicting an example of a cross sectional photograph of a non-through hole in a substrate obtained in Example 5; and

FIG. 15 is a diagram depicting an example of a cross sectional photograph of a non-through hole in a substrate obtained in Example 6.

### DETAILED DESCRIPTION OF THE PREFERRED EMBODIMENTS

In the following, with reference to drawings, embodiments of the present invention will be described.

(Method of Manufacturing Substrate with Through-Electrode According to the Related Art)

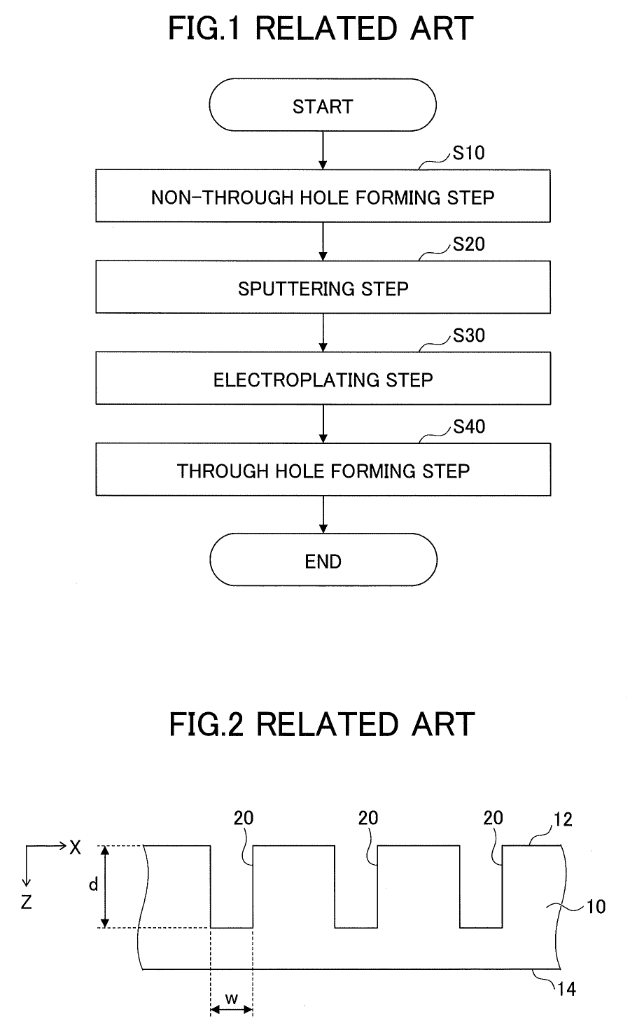

In order to understand the present invention, with reference to FIGS. 1 to 7, a method of manufacturing a substrate with through-electrode according to the related art will be briefly described.

FIG. 1 is a flowchart schematically depicting the method of manufacturing a substrate with through-electrode according to the related art (in the following, simply referred to as a “conventional manufacturing method”).

As shown in FIG. 1, the conventional manufacturing method includes

(1) Forming a non-through hole in a substrate (non-through hole formation step: Step S10);

(2) Depositing a metal layer in the non-through hole by using a sputtering method (sputtering step: Step S20);

(3) Filling the non-through hole with a conductive material by using an electroplating method (electroplating step: Step S30); and

(4) Removing the conductive material on the surface having the non-through hole by using a chemical mechanical polishing (CMP) method, and grinding the other surface of the substrate, to form a through hole (through hole formation step: Step S40).

With reference to FIGS. 2 to 7, the above-described processes will be described below in detail.

(Step S10)

A substrate to be worked is provided. The substrate has a first surface and a second surface. The substrate is, for example, a glass substrate or a semiconductor substrate.

A non-through hole is formed or a plurality of non-through holes are formed on the first surface of the substrate by using a laser processing method, for example.

FIG. 2 is a diagram schematically depicting a cross section of a substrate 10 having a first surface 12 and a second surface 14. Non-through holes 20 are formed on the first surface 12. As shown in FIG. 2, the non-through holes 20 typically have high aspect ratios. The “aspect ratio” is a ratio of a depth d of the non-through hole 20 to the maximum width (typically a diameter) w, d/w.

(Step S20)

A metal layer is deposited by using a sputtering method inside the non-through hole 20 formed in Step S10.

In Step S20, a seeding layer is formed in the non-through hole 20. The metal layer functions as a seeding layer. The seeding layer allows a conductive material to be electrode posited in the non-through hole 20 in a subsequent electroplating step (Step S30). Thus, the non-through hole 20 is filled with the conductive material.

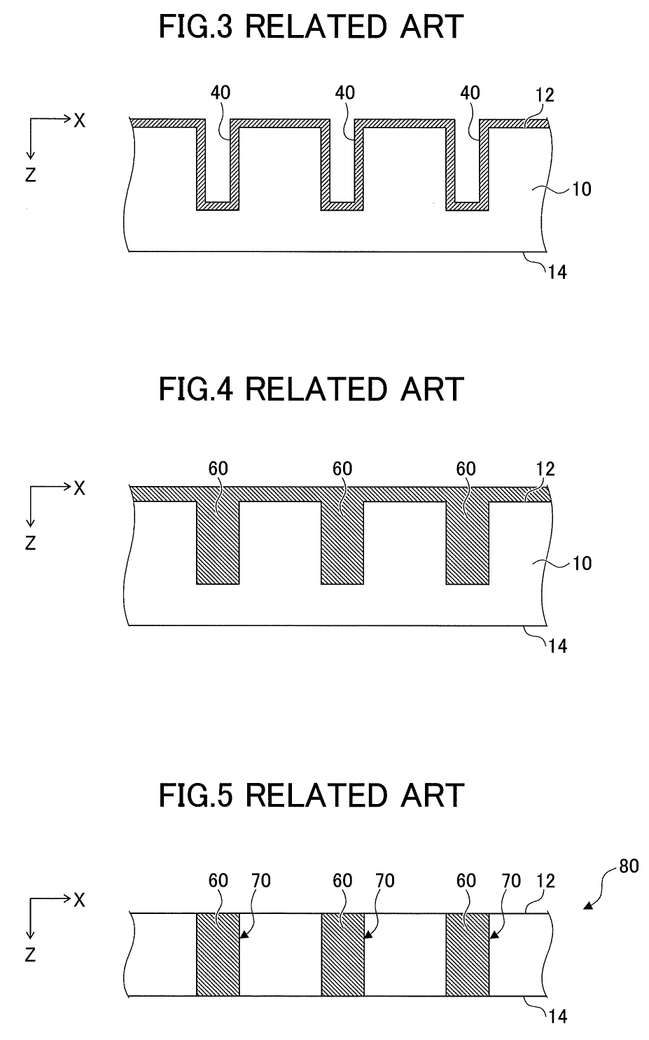

FIG. 3 is a diagram depicting a metal layer 40 deposited on the first surface 12 of the substrate 10 and in the non-through holes 20.

(Step S30)

By using an electroplating method, the non-through hole 20 is filled with a conductive material. As described above, the metal layer 40 is deposited inside the non-through hole 20. Thus, even when the substrate 10 is made of a non-conductive material, such as a glass, a conductive material is electrode posited inside the non-through hole 20 by using an electroplating method, and the non-through hole 20 is filled with the conductive material.

As shown in FIG. 4, the conductive material 60 is filled in the non-through holes 20. Typically, the conductive material 60 is also formed on the first surface 12 of the substrate 10. For clarity, the metal layer 40 is omitted in FIG. 4.

(Step S40)

The conductive material deposited on the first surface 12 of the substrate 10 is removed by using a CMP method, and the second surface 14 of the substrate 10 is ground until end portions of the non-through holes 20 appear on the second surface 14 of the substrate 10. FIG. 5 is a diagram schematically showing a cross section of the substrate 10 after Step S40. As shown in FIG. 5, according to Step S40, the first surface 12 communicates with the second surface 14 via the non-through hole 20. Thus, a through hole 70, which is filled with a conductive material 60, is formed.

According to the above-described processes, a substrate 80 with through-electrodes is manufactured.

In the conventional manufacturing methods, there is a problem that the through holes 70 formed in the substrate with through-electrodes 80 are not sufficiently filled with the conductive material 60.

In the conventional manufacturing methods, an aspect ratio of the non-through hole 20 formed in the non-through hole formation step (Step S10) is high, and the metal layer 40 is not deposited over the entire surface of the non-through hole 20 (wall surface forming the non-through hole 20) in the sputtering step (Step S20).

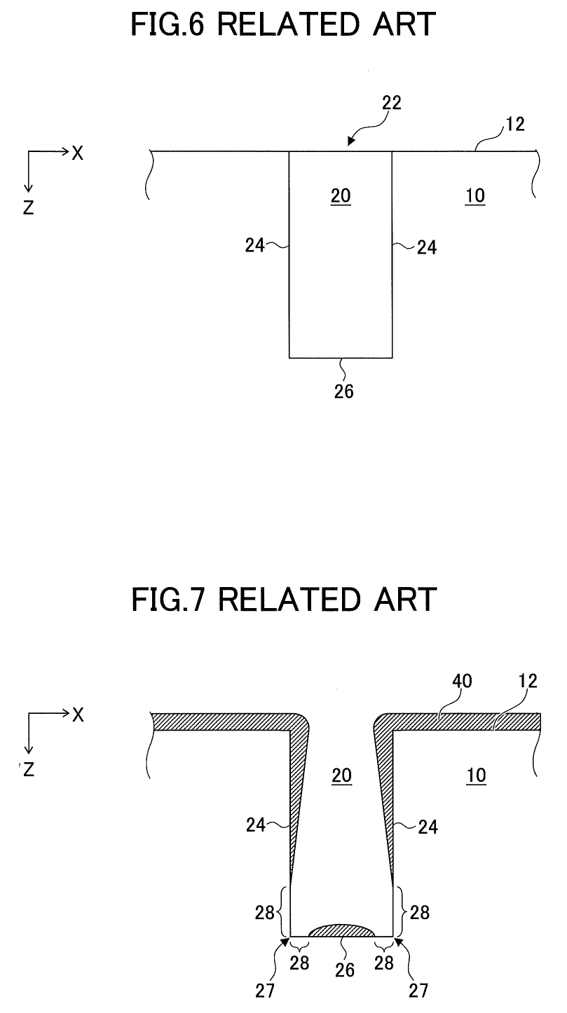

The problem will be further described with reference to FIGS. 6 and 7.

FIG. 6 is an enlarged diagram schematically showing a cross section of the non-through hole 20 before the sputtering step (Step S20). FIG. 7 is an enlarged diagram schematically shows a cross section of the non-through hole 20 after the sputtering step (Step S20).

As shown in FIG. 6, the non-through hole 20 includes an opening 22 with respect to the first surface 12 of the substrate 10; side walls 24; and a bottom wall 26.

After the sputtering step, a metal layer 40 is deposited on the side walls 24 and the bottom wall 26 of the non-through hole 20, as shown in FIG. 7.

When the aspect ratio of the non-through hole 20 is high, a thickness of the metal layer 40 on the side walls 24 decreases in the depth direction of the non-through hole 20. As a result, the metal layer 40 is not deposited in a boundary region 27 between the side wall 24 and the bottom wall 26 of the non-through hole 20 and in regions adjacent to the boundary region 27 (referred to as “adjacent regions 28”).

In the electroplating step (Step S30) with the above-described metal layer 40, the conductive material 60 is not electrode posited in the part where the metal layer 40 is not deposited. After Step S30, a void that is not filled with the conductive material 60 appears.

The void remains after Step S40. Thus, the through hole 70 includes a part which is not sufficiently filled with the conductive material 60.

In the conventional manufacturing methods, there is a problem that the through-hole 70 is not sufficiently filled with the conductive material 60 in a substrate with through-electrode.

An embodiment of the present invention solves the problem, as will be described in detail below.

(Substrate Having Non-Through Hole According to Embodiment of Present Invention)

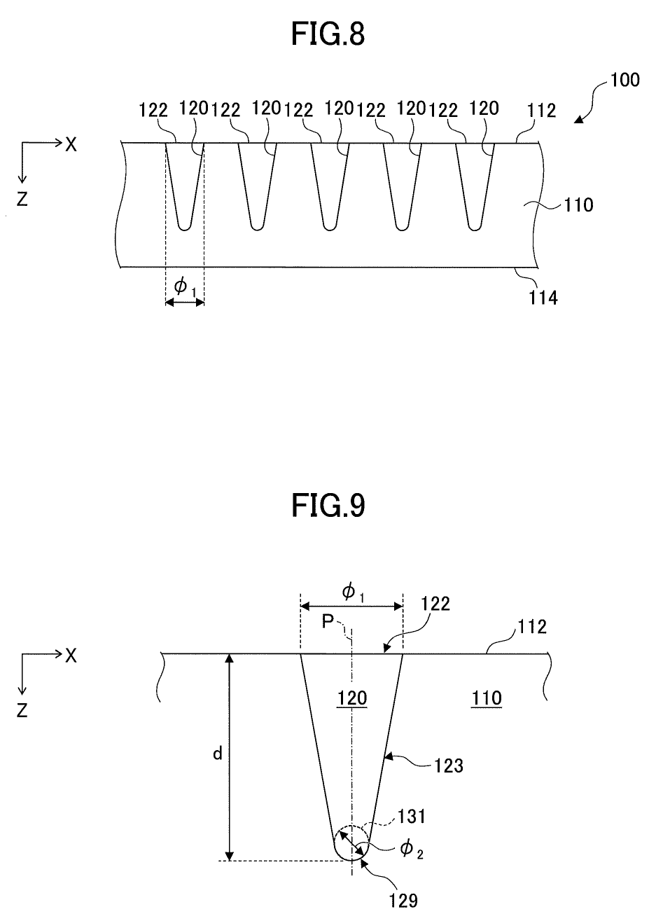

Referring to FIGS. 8 to 10, a substrate having a non-through hole according to an embodiment of the present invention will be described.

FIG. 8 is a diagram schematically depicting a cross section of the substrate having a non-through hole according to the embodiment of the present invention (hereinafter referred to as a “first member”).

As shown in FIG. 8, the first member 100 has a substrate 110 having a first surface 112 and a second surface 114. A material of the substrate 110 is not particularly limited. The substrate 110 may be made of, for example, an inorganic material, such as a glass, or of a semiconductor material, such as silicon.

A plurality of non-through holes 120 are formed on the first surface 112 of the substrate 110. Moreover, openings 122 of the non-through holes 120 appear on the first surface 112 of the substrate 110. The openings 122 have a circular shape with a diameter ϕ₁.

Note that the diameter ϕ₁ of the openings 122 is determined as follows.

An image of the surface of the glass substrate, on which the non-through holes are formed, is captured by using an optical microscope or a scanning type electron microscope.

In the captured image, three non-through holes are selected. Then, the greatest diameters of the openings of the three non-through holes are measured, respectively.

An arithmetic average value of the three measured diameters is determined to be the diameter C.

In the example illustrated in FIG. 8, five non-through holes 120 are shown. The number of non-through holes 120 is not particularly limited. For example, the number of non-through holes 120 may be one. Moreover, shapes of a plurality of non-through holes 120 may be different from each other.

FIG. 9 is an enlarged diagram depicting a cross section of the non-through hole 120 in the substrate 110 illustrated in FIG. 8. The cross section illustrated in FIG. 9 (hereinafter also referred to as a “first cross section”) includes a stretching axis P of the non-through hole 120. The stretching axis P is perpendicular to the opening 122 at the center of the opening 122 of the non-through hole 120. The stretching axis P extends from the center of the opening 122 to the end portion 129.

In the present application, the “first cross section” is observed as follows.

By using a cutting tool the substrate 110 is cut at a point separated from the non-through hole 120 by 10 to 100 μm so as not to damage the non-through hole 120. The “first cross section” can be observed from a cut surface of the substrate 110 by using a transmission type optical microscope. The substrate 110 is preferably cut in a direction orthogonal to the first surface 112.

Alternatively, the cross section of the substrate 110 is ground so that a “first cross section” of the non-through hole 120 appears, which is observed directly.

As shown in FIG. 9, the first cross section of the non-through hole 120 has side portions 123 and an end portion 129. That is, the non-through hole 120 includes an opening 122 with respect to the substrate 110; side walls (corresponding to side portions 123 in the first cross section); and a bottom wall (corresponding to an end portion 129 in the first cross section).

The end portion 129 in the first cross section has a “round shape”. Thus, as shown in FIG. 9, in the first cross section, the shape of the end portion 129 is approximated by a circle (referred to as an “approximate circle”) 131 with a diameter ϕ₂.

The term “round shape” refers to a shape having a curve, and it is not limited to a shape having a smooth curve.

Moreover, a diameter of the approximate circle is determined from a diameter of a circle obtained by applying a least squares method to the end portion 129 in the first cross section. As an example, the approximate circle is approximated to be a circumscribed circle of a polygon formed of points deviated from a line of the side portion 123 (line L, described later), in the end portion 129 in the first cross section that is continuous from the side portion 123.

In the first member 100, a depth d of the non-through holes 120 is, for example, 30 μm or more.

In the specification of the present application, the depth d is a distance from the surface of the glass substrate on the side of the opening of the non-through hole in a direction parallel to the stretching axis, to the deepest part (end portion) of the non-through hole. The depth d is determined from an image of a cross section captured by using a transmission type optical microscope or a scanning type electron microscope, by analyzing (measuring) the maximum depth of the non-through hole.

The depth d is preferably 40 μm or more, and more preferably 50 μm or more. The depth d is preferably 400 μm or less, more preferably 300 μm or less, and particularly preferably 250 μm or less. Moreover, the depth d preferably falls within a range of 30 μm to 400 μm, more preferably within a range of 40 μm to 300 μm, and particularly preferably within a range of 50 μm to 250 μm.

Moreover, the diameter ϕ₁ of the opening 122 of the non-through hole 120 falls within a range of, for example, 5 μm to 200 μm. The diameter ϕ₁ is, for example, 5 μm or more, preferably 10 μm or more, and more preferably 15 μm or more. The diameter ϕ₁ is, for example, 200 μm or less, preferably 150 μm or less, and more preferably 100 μm or less. Moreover, the diameter ϕ₁ preferably falls within the range of 10 μm to 150 μm, and more preferably within the range of 15 μm to 100 μm.

Furthermore, a ratio of the diameter ϕ₂ of the approximate circle 131 of the end portion 129 to the diameter ϕ₁ of the opening 122, i.e. a ratio ϕ₂/ϕ₁, falls, for example, within a range of 0.03 to 0.9. The ratio ϕ₂/ϕ₁ is, for example, 0.03 or more, preferably 0.05 or more, and more preferably 0.1 or more. The ratio ϕ₂/ϕ₁ is, for example, 0.9 or less, preferably 0.8 or less, more preferably 0.6 or less, and particularly preferably 0.45 or less. Moreover, the ratio ϕ₂/ϕ₁ preferably falls within a range of 0.05 to 0.8, and more preferably within the range of 0.05 to 0.6.

Furthermore, the first member 100 has a feature that “tapered angles (α)” of the non-through holes 120 fall within a range of 2° to 80°.

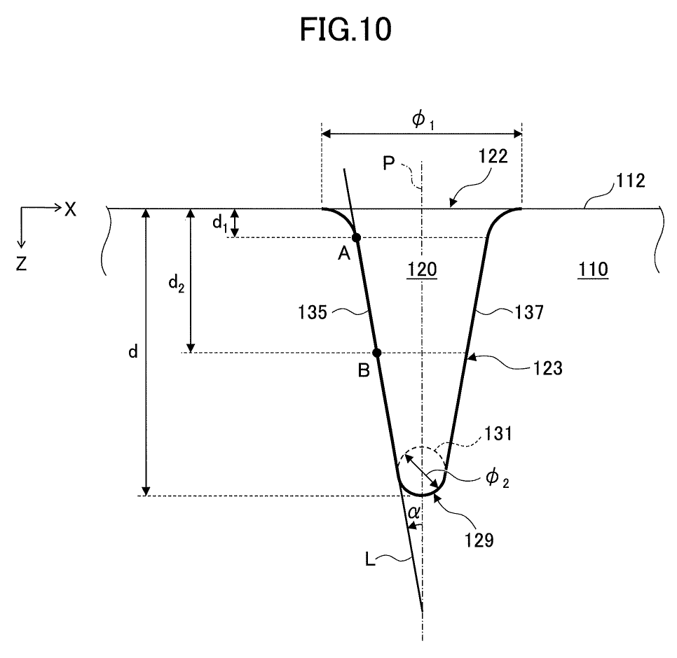

In the following, with reference to FIG. 10, the “tapered angle” of the non-through hole 120 will be described.

FIG. 10 is a diagram schematically depicting an example of a cross section of the non-through hole 120 included in the first member 100. Similar to FIG. 9, the cross section includes the stretching axis P of the non-through hole 120. Thus, the cross section is a first cross section.

As shown in FIG. 10, the non-through hole 120 has side portions 123 and an end portion 129. In FIG. 10, the opening 122 of the non-through hole 120 is defined by a curved surface smoothly connecting the side wall (the side portions 123) and the first surface 112. The present invention is not limited to the configuration. For example, the opening 122 of the non-through hole 120 may be defined by an edge between the side wall (the side portions 123) and the first surface 112, as shown in FIG. 9.

Portions of the substrate 110 that define the side walls of the non-through hole 120, in the first cross section, will be referred to as a first wall line 135 (left portion in the drawing) and a second wall line 137 (right portion in the drawing). The first wall line 135 and the second wall line 137 are approximately symmetric with respect to the stretching axis P.

The “tapered angle” is defined as follows. In the first cross section, a point A is located on the first wall line 135 and is separated from the opening 122 by a first distance d₁ (d₁=0.1×d) in the depth direction of the non-through hole 120, i.e. in a direction parallel to the stretching axis, where d is the depth of the non-through hole 120. Moreover, a point B is located on the first wall line 135 and is separated from the opening 122 by a second distance d₂ (d₂=0.5×d) in the depth direction of the non-through hole 120, i.e. in the direction parallel to the stretching axis.

A straight line L connecting the point A and the point B, and the stretching axis P intersect at an angle. The angle between the straight line L and the stretching axis P is referred to as a tapered angle α (0°<α<90°).

Note that a straight line connecting two points on the second wall line 137 instead of the first wall line 135, may be used to determine the tapered angle α. The tapered angle (α1) determined using the straight line connecting the two points on the first wall line 135, and the tapered angle (α2) determined using the straight line connecting the two points on the second wall line 137 are preferably the same, but may be different from each other. Even if the tapered angles α1 and α2 are different from each other, the tapered angles α1 and α2 are required to fall within the range of 2° to 80°.

However, the straight line L and the stretching axis P are required to intersect below the opening 122 (in FIG. 10, at a point with a positive Z component) and not to intersect above the opening 122 (in FIG. 10, at a point with a negative Z component). In the latter case, the non-through hole has a “reversed tapered shape,” i.e. a shape that increases in diameter in the depth direction, and with such a shape the aforementioned problem is not solved.

The tapered angle α is 2° or more, preferably 4° or more, and more preferably 5° or more. The tapered angle α is 80° or less, preferably 60° or less, more preferably 45° or less, and particularly preferably 15° or less. Moreover, the tapered angle α preferably falls within the range of 4° to 45°, and more preferably within the range of 5° to 15°.

The first member 100 including the non-through holes 120 having the above-described structure does not generate an unusable region, in which a metal layer is not deposited, in the non-through hole 120 in the sputtering step. Thus, when the first member 100 is used, a metal layer is deposited in the sputtering step easily over the entirety of the side walls and the bottom wall of the non-through hole 120.

Thus, in the first member 100, in the electroplating step, the conductive material can be electrically deposited over the entirety of the side wall and the bottom wall of the non-through hole 120. Thus, the non-through hole 120 is filled with a conductive material, and the problem of voids in non-through holes or through holes in the related art is solved.

(Method of Manufacturing Substrate Having Non-Through Hole According to the Embodiment of the Present Invention)

A method of manufacturing a substrate having a non-through hole according to an embodiment of the present invention will be described.

The method of manufacturing a substrate having a non-through hole according to the embodiment of the present invention (hereinafter referred to as a “first manufacturing method”) includes

(i) Irradiating the substrate with laser light to form a non-through hole (Step S110); and

(ii) Etching the substrate in which the non-through hole is formed (Step S120).

Processes of the steps will be described below. In the following, the steps of the first manufacturing method will be described for the first member 100, as an example. Thus, the reference signs used in FIGS. 8 to 10 will be used.

(Step S110)

A substrate 110 to be worked is provided. As described above, the substrate 110 may be a glass substrate or a semiconductor substrate (e.g. a silicon substrate).

A thickness of the substrate 110 is not particularly limited. The thickness of substrate 110 may, for example, fall within the range of 0.04 mm to 2.0 mm.

A non-through hole 120 is formed or a plurality of non-through holes 120 are formed on one surface (first surface 112) of the substrate 110.

The non-through hole 120 may be formed by irradiating the substrate with laser light. For the laser light source, a CO₂ laser, a YAG laser, or the like is used.

(Step S120)

The substrate 110 having a non-through hole 120 is etched. According to the etching, the non-through holes 120 formed in Step S110 have a desired shape. That is, a non-through hole 120 having a round end portion 129 with a diameter an opening 122 with a diameter ϕ₁, and a ratio ϕ₂/ϕ₁ and a tapered angle α that fall within predetermined ranges is formed.

The condition for the etching process is not particularly limited. For example, when the substrate 110 is a glass substrate, a wet etching is performed. For the etchant, for example, a mixed acid solution of fluoric acid (HF) and hydrochloric acid (HCl) may be used.

Alternatively, if the substrate 110 is a silicon substrate, a dry etching may be performed. In this case, for example, a gas such as sulfur hexafluoride (SF₆) may be used.

Thus, by combining the irradiation with laser light with the etching process, the first member 100 with the non-through hole 120 having the desired shape is manufactured.

In addition, the following processes may be performed for the first member 100.

(iii) Depositing a metal layer in the non-through hole by using a sputtering method;

(iv) Filling the non-through hole with a conductive material by using an electroplating method; and

(v) Removing the conductive material on the surface of the substrate with the non-through hole by grinding by using a CMP method or the like, and grinding the other surface to form a through hole.

For example, in the case of performing Step (iii), a substrate having a non-through hole in which a seeding layer is deposited is manufactured. Moreover, in the case of performing Steps (iii) and (iv), a substrate having a non-through hole filled with a conductive material is manufactured. Furthermore, in the case of performing Steps (iii) to (v), a substrate having through-hole filled with a conductive material, i.e. a substrate with through-electrode, is manufactured. In particular, in the case of performing Steps (iii) to (v) for a glass substrate, a glass-core substrate with through-electrode is manufactured.

Processes of Steps (iii) to (v) are obvious for a person skilled in the art, and a detailed explanation thereof will be omitted (See, for example, the descriptions for Steps S20 to S40).

### EXAMPLES

In the following, examples of the present invention will be described. In the following description, Examples 1 to 4 are practical examples, and Examples 5 and 6 are comparative examples.

### Example 1

By using the following method, a substrate having a non-through hole was manufactured.

A glass substrate (non-alkaline glass) with a thickness of 500 μm was provided. A surface (the first surface) of the glass substrate was irradiated with laser light, and a non-through hole was formed in the glass substrate.

For laser light, a UV nanosecond pulse laser with pulse energy of 20 μJ was used. A number of shots of laser light was 100.

The glass substrate was immersed in an etchant, and a wet etching was performed.

For the etchant, a mixed acid solution of fluoric acid and hydrochloric acid (HF:HCl=1:5) was used. An etching rate was set to 1.5 μm/minute, and an etching amount was set to 20 μm, on the basis of the thickness of the glass substrate.

According to the above-described procedure, the substrate having a non-through hole (hereinafter referred to as “Sample 1”) was manufactured.

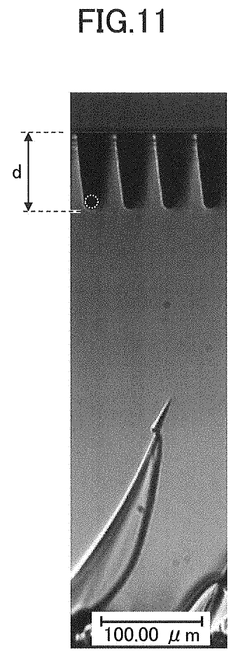

FIG. 11 is a diagram depicting an example of a cross section of a non-through hole in Sample 1 (photograph captured by using a transmission type optical microscope).

As shown in FIG. 11, in Sample 1, a non-through hole having a cross section including a stretching axis having a round shaped end portion was formed. Moreover, the non-through hole had a tapered shape, i.e. a diameter decreases in the depth direction.

### Example 2

By using the same method as Example 1, a substrate having a non-through hole was manufactured. However, in Example 2, the number of shots of laser light was 200.

According to the above-described procedure, the substrate having a non-through hole (hereinafter, referred to as “Sample 2”) was manufactured.

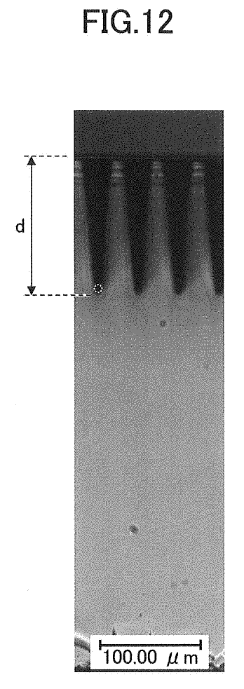

FIG. 12 is a diagram depicting an example of a cross section of a non-through hole in Sample 2.

As shown in FIG. 12, in Sample 2, a non-through hole having a cross section including a stretching axis having a round shaped end portion was formed. Moreover, the non-through hole had a tapered shape, i.e. a diameter decreases in the depth direction.

### Example 3

By using the same method as Example 1, a substrate having a non-through hole was manufactured. However, in Example 3, the number of shots of laser light was 400.

According to the above-described procedure, the substrate having a non-through hole (hereinafter, referred to as “Sample 3”) was manufactured.

In Sample 3, a non-through hole having a cross section including a stretching axis having a round shaped end portion was formed. Moreover, the non-through hole had a tapered shape, i.e. a diameter decreases in the depth direction.

### Example 4

By using the following method, a substrate with non-through hole was manufactured.

A glass substrate (non-alkaline glass) with a thickness of 420 μm was provided. A surface (the first surface) of the glass substrate was irradiated with laser light, and a non-through hole was formed in the glass substrate.

For laser light, a CO₂ laser of 50 W was used. An irradiation time of laser light was 45 μsec.

The glass substrate was immersed in an etchant, and a wet etching was performed.

For the etchant, a mixed acid solution of fluoric acid and hydrochloric acid (HF:HCl=1:5) was used. An etching rate was set to 1.5 μm/minute, and an etching amount was set to 40 μm, on the basis of the thickness of the glass substrate.

According to the above-described procedure, the substrate having a non-through hole (hereinafter referred to as “Sample 4”) was manufactured.

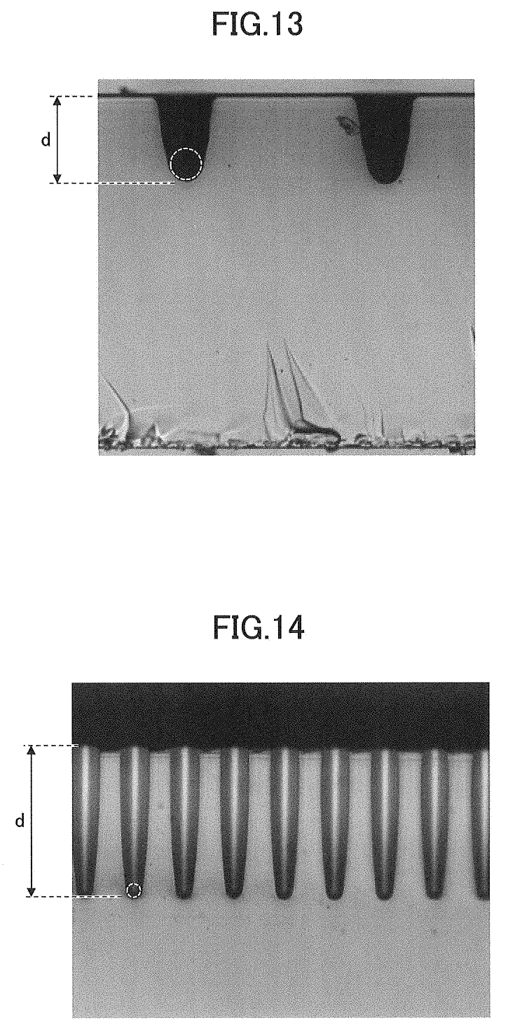

FIG. 13 is a diagram depicting an example of a cross section of a non-through hole in Sample 4.

As shown in FIG. 13, in Sample 4, a non-through hole having a cross section including a stretching axis having a round shaped end portion was formed. Moreover, the non-through hole had a tapered shape, i.e. a diameter decreases in the depth direction.

### Example 5

By using the following method, a substrate with non-through hole was manufactured.

A glass substrate (quartz glass) with a thickness of 530 μm was provided. A surface (the first surface) of the glass substrate was irradiated with laser light, and a non-through hole was formed in the glass substrate.

For laser light, a UV nanosecond pulse laser with pulse energy of 40 μJ was used. A number of shots of laser light was 180.

The glass substrate was immersed in an etchant, and a wet etching was performed.

For the etchant, fluoric acid was used. An etching rate was set to 0.3 μm/minute, and an etching amount was set to 20 μm on the basis of the thickness of the glass substrate.

According to the above-described procedure, the substrate having a non-through hole (hereinafter referred to as “Sample 5”) was manufactured.

FIG. 14 is a diagram depicting an example of a cross section of a non-through hole in Sample 5.

### Example 6

By using the following method, a substrate with non-through hole was manufactured.

A glass substrate (non-alkaline glass) with a thickness of 200 μm was provided. A surface (the first surface) of the glass substrate was irradiated with laser light, and a non-through hole was formed in the glass substrate.

For laser light, a picosecond pulse laser with pulse energy of 100 μJ was used. A wavelength of the laser light was set to 532 nm, and a number of shots of the laser light was one.

The glass substrate was immersed in an etchant, and a wet etching was performed.

For the etchant, a mixed acid solution of fluoric acid and hydrochloric acid (HF:HCl=1:5) was used. An etching rate was set to 0.2 μm/minute, and an etching amount was set to 30 μm, on the basis of the thickness of the glass substrate.

According to the above-described procedure, the substrate having a non-through hole (hereinafter referred to as “Sample 6”) was manufactured.

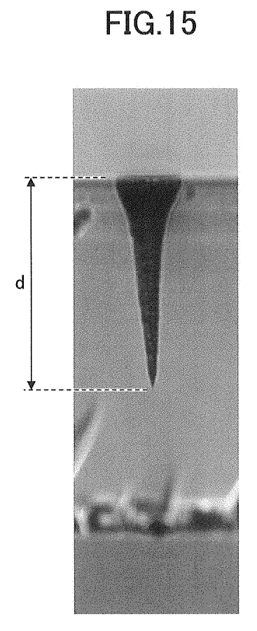

FIG. 15 is a diagram depicting an example of a cross section of a non-through hole in Sample 6.

TABLE 1, in the following, shows the shape parameters of non-through holes obtained for Samples, as a whole.

TABLE 1

| | diameter | | diameter | | |
|---|---|---|---|---|---|
| | φ₁ of | | φ₂ of end | | tapered |
| | opening | depth d | portion | ratio | angle α |
| Sample | (μm) | (μm) | (μm) | φ₂/φ₁ | (degrees) |
| 1 | 25 | 71 | 10.6 | 0.42 | 4.8 |
| 2 | 25 | 130 | 6.4 | 0.26 | 5.8 |
| 3 | 25 | 240 | 1.7 | 0.068 | 2.5 |
| 4 | 68.6 | 94 | 36.5 | 0.53 | 9.8 |
| 5 | 24 | 120 | 12.6 | 0.53 | 0.7 |
| 6 | 30 | 98 | — | — | 12.3 |

From TABLE 1, for Samples 1 to 4, the diameter ϕ₁ of the opening fell within the range of 5 μm to 200 μm, and the depth d was 30 μm or more. Moreover, for Samples 1 to 4, a shape of the end portion of the non-through hole was approximated by a circle, and a ratio of the diameter ϕ₂ of the approximate circle of the end portion to the diameter ϕ₁ of the opening, ϕ₂/ϕ₁, fell within a range of 0.03 to 0.9. Furthermore, the tapered angle α fell within a range of 2° to 15°.

For Sample 5, the tapered angle α was less than 2°. Moreover, for Sample 6, the end portion of the non-through hole was pointed.

From the above-described results, for Samples 1 to 4, the metal layer is deposited easily on the side portions and the end portion of the non-through hole compared with Samples 5 and 6 in the sputtering step.

### REFERENCE SIGNS LIST

10 substrate
12 first surface
14 second surface
20 non-through hole
22 opening
24 side wall
26 bottom wall
27 boundary region
28 adjacent region
40 metal layer
60 conductive material
70 through hole
80 substrate with through-electrode
100 first member (substrate having a non-through hole according to embodiment)
110 substrate
112 first surface
114 second surface
120 non-through hole
122 opening
123 side portion
129 end portion
131 approximate circle
135 first wall line
137 second wall line

What is claimed is:

1. A substrate having a non-through hole,
wherein the non-through hole has an opening with a diameter ϕ₁ that falls within a range of 5 μm to 200 μm, and has a depth d of 30 μm or more,
wherein the non-through hole has a rounded end portion, and in a cross section of the non-through hole including a stretching axis of the non-through hole, a shape of the end portion is approximated by a circular arc with a diameter and a ratio of the diameters ϕ₂/ϕ₁ falls within a range of 0.03 to 0.9,
wherein the cross section includes a first wall line and a second wall line that define side walls of the non-through hole, the first wall line and the second wall line being symmetric with respect to the stretching axis of the non-through hole, and
wherein a tapered angle α formed by a line L and the stretching axis falls within a range of 2° to 80°, the line L connecting a point A on the first wall line separated from the opening by a distance d₁ (d₁=0.1×d) in a direction parallel to the stretching axis and a point B on the first wall line separated from the opening by a distance d₂ (d₂=0.5×d) in the direction parallel to the stretching axis.

2. The substrate according to claim 1,
wherein the tapered angle α falls within a range of 2° to 15°.

3. The substrate according to claim 1,
wherein the non-through hole is filled with a conductive material.

4. The substrate according to claim 1,
wherein the opening of the non-through hole is defined by a curved surface smoothly connecting the side walls and a surface on which the non-through hole is formed.

5. The substrate according to claim 1,
wherein the opening of the non-through hole is defined by an edge between the side walls and a surface on which the non-through hole is formed.

6. The substrate according to claim 1,
wherein the ratio ϕ2/ϕ1 falls within a range of 0.05 to 0.45.

7. The substrate according to claim 1,
wherein the substrate is a glass substrate.

8. The substrate according to claim 7,
wherein the substrate is a glass core substrate.
